(19) United States
(12) Patent Application Publication
(10) Pub. No.: US 2015/0236076 A1
(43) Pub. Date: Aug. 20, 2015

(54) ORGANIC LIGHT EMITTING DISPLAY PANEL AND METHOD OF MANUFACTURING THE SAME

(71) Applicant: SAMSUNG DISPLAY CO., LTD., Yongin-City (KR)

(72) Inventors: Mun-Ki Sim, Seoul (KR); Jae-Byung Park, Seoul (KR); Baek-Hee Lee, Yongin-si (KR); Jun-Han Lee, Incheon (KR)

(21) Appl. No.: 14/523,763

(22) Filed: Oct. 24, 2014

(30) Foreign Application Priority Data
Feb. 14, 2014 (KR) 10-2014-0017052

(51) Int. Cl. H01L 27/32; G09G 3/32

(52) U.S. Cl. CPC H01L 27/3218; G09G 3/3275; G09G 2300/0439; G09G 2300/0426; H01L 51/56

(57) ABSTRACT

An organic light emitting display panel includes a display substrate, an insulation layer on the display substrate, the insulation layer having a first plane, a second plane, and a third plane that respectively correspond to a first sub-pixel area, a second sub-pixel area, and a third sub-pixel area, a first electrode, a second electrode, and a third electrode respectively on the first plane, the second plane, and the third plane, a pixel defining layer on the insulation layer, first, second, and third organic light emitting structures respectively on the first, second, and third electrodes, and a common electrode on the first, second, and third organic light emitting structures. At least one of the first, second, and third planes is inclined with respect to the display substrate.

### CROSS REFERENCE TO RELATED APPLICATION

This application claims priority to and the benefit of Korean Patent Applications No. 10-2014-0017052, filed on Feb. 14, 2014 in the Korean Intellectual Property Office (KIPO), the disclosure of which is hereby incorporated by reference herein in its entirety.

### BACKGROUND

1. Field

Example embodiments of the present disclosure relate to display devices. More particularly, example embodiments of the present disclosure relate to organic light emitting display panels included in the display devices, and methods of manufacturing the same.

2. Discussion of Related Art

An organic light emitting display (OLED) device may display information such as images and characters using (or utilizing) light generated from an organic layer therein. As for the organic light emitting display device, light may be generated by combination of holes from an anode and electrons from a cathode at the organic layer between the anode and the cathode.

In general, a pixel area (and a sub-pixel area) of an organic light emitting display panel included in an organic light emitting display device is positioned parallel to a display substrate. Further, recently, a micro cavity structure that performs an adjustment to increase the efficiency through the adjustment of the thicknesses of the red, green and blue color organic light emitting structures may be used (or utilized), and the light efficiency may be partly increased. However, when the micro cavity structure is adopted, the efficiency may be increased, but a problem of side color shift may occur. Especially, WAD (White Angular Dependency) whereby white as seen from the front and white as seen from a side (e.g., left or right side) become different from each other may occur. For example, a displaying defect such as blue color shift (in the micro cavity structure of the organic light emitting display panel), yellow color shift or red color shift (in non-resonance structure of the organic light emitting display panel) from the side may occur.

Further, organic luminescent materials emitting a blue color light have a short lifetime compared to other organic luminescent materials emitting other colors of light. Thus, lifetime of the organic light emitting display panel depends on a blue color light emitting diode (i.e., the blue color organic light emitting structure).

### SUMMARY

Aspects of example embodiments are directed toward an organic light emitting display panel including sub-pixel regions formed on inclined planes.

Aspects of example embodiments are directed toward an organic light emitting display panel including pixels formed on common inclined planes.

Aspects of example embodiments are directed toward a method of manufacturing the organic light emitting display panel.

According to example embodiments, an organic light emitting display panel includes: a first sub-pixel area, a second sub-pixel area adjacent to the first sub-pixel area, and a third sub-pixel area adjacent to the second sub-pixel area; a display substrate; an insulation layer on the display substrate, the insulation layer having: a first plane corresponding to the first sub-pixel area; a second plane corresponding to the second sub-pixel area; and a third plane corresponding to the third sub-pixel area, at least one of the first, second, and third planes being inclined with respect to the display substrate; first, second, and third electrodes respectively on the first, second, and third planes; a pixel defining layer on the insulation layer, the pixel defining layer defining the first, second, and third sub-pixel areas; first, second, and third organic light emitting structures respectively on the first, second, and third electrodes, the first, second, and third organic light emitting structures being parallel to the first, second, and third planes, respectively; and a common electrode on the first, second, and third organic light emitting structures.

In example embodiments, all of the first, second, and third planes are inclined with respect to the display substrate.

In example embodiments, the first and third planes are inclined in a first direction with respect to the display substrate, and the second plane is inclined in a second direction opposite to the first direction with respect to the display substrate.

In example embodiments, the first and third planes have inclined angles from about 10 degrees to about 20 degrees with respect to the display substrate, and the second plane may has an inclined angle from about 160 degrees to about 170 degrees with respect to the display substrate.

In example embodiments, each of the first, second, and third planes has a convex curved surface.

In example embodiments, the first, second, and third planes are inclined in a same direction with respect to the display substrate.

In example embodiments, the first, second, and third planes have inclined angles from about 10 degrees to about 20 degrees with respect to the display substrate.

In example embodiments, the insulation layer is formed by a photolithography process, an imprinting process, a bar-coating process, or a 3-dimensional (3D) printing process.

According to other example embodiments, an organic light emitting display panel includes: a first pixel area having a first sub-pixel area, a second sub-pixel area, and a third sub-pixel area; a second pixel area having a fourth sub-pixel area, a fifth sub-pixel area, and a sixth sub-pixel area, the second pixel area being adjacent to the first pixel area; a display substrate; an insulation layer on the display substrate, the insulation layer having: a first common plane corresponding to the first, second, and third sub-pixel areas; and a second common plane corresponding to the fourth, fifth, and sixth sub-pixel areas, the first and second common planes being inclined with respect to the display substrate; first, second, and third electrodes respectively corresponding to the first, second, and third sub-pixel areas on the first common plane; fourth, fifth, and sixth electrodes respectively corresponding to the fourth, fifth, and sixth sub-pixel areas on the second common plane; a pixel defining layer on the insulation layer, the pixel defining layer defining the first, second, third, fourth, fifth, and sixth sub-pixel areas; first, second, and third organic light emitting structures respectively on the first, second, and third electrodes, the first, second, and third organic light emitting structures being parallel to the first common plane; fourth, fifth, and sixth organic light emitting structures respectively on the fourth, fifth, and sixth electrodes, the fourth, fifth, and sixth organic light emitting structures being parallel to the second common plane; and a common electrode on the first, second, third, fourth, fifth, and sixth organic light emitting structures.

In example embodiments, the first common plane is inclined in a first direction with respect to the display substrate, and the second common plane is inclined in a second direction opposite to the first direction with respect to the display substrate.

In example embodiments, the first common plane has an inclined angle from about 10 degrees to about 20 degrees with respect to the display substrate, and the second common plane has an inclined angle from about 160 degrees to about 170 degrees with respect to the display substrate.

In example embodiments, each of the first and second common planes has a convex curved surface.

In example embodiments, the insulation layer is formed by a photolithography process, an imprinting process, a bar-coating process, or a 3-dimensional (3D) printing process.

According to example embodiments, a method of manufacturing an organic light emitting display panel including a first sub-pixel area, a second sub-pixel area adjacent to the first sub-pixel area, and a third sub-pixel area adjacent to the second sub-pixel area includes: forming an insulation layer having a first plane corresponding to the first sub-pixel area, a second plane corresponding to the second sub-pixel area, and a third plane corresponding to the third sub-pixel area on a display substrate, at least one of the first, second, and third planes being inclined with respect to the display substrate; forming first, second, and third electrodes on the first, second, and third planes, respectively; forming a pixel defining layer on the insulation layer, the pixel defining layer defining the first, second, and third sub-pixel areas; forming first, second, and third organic light emitting structures on the first, second, and third electrodes, respectively, the first, second, and third organic light emitting structures being parallel to the first, second, and third planes, respectively; and forming a common electrode on the first, second, and third organic light emitting structures.

In example embodiments, the first and third planes are inclined in a first direction with respect to the display substrate, and the second plane is inclined in a second direction opposite to the first direction with respect to the display substrate.

In example embodiments, the first and third planes have inclined angles from about 10 degrees to about 20 degrees with respect to the display substrate, and the second plane has an inclined angle from about 160 degrees to about 170 degrees with respect to the display substrate.

In example embodiments, each of the first, second, and third planes has a convex curved surface.

In example embodiments, the first, second, and third planes are inclined in a same direction with respect to the display substrate.

In example embodiments, the first, second, and third planes have inclined angles from about 10 degrees to about 20 degrees with respect to the display substrate.

In example embodiments, the insulation layer is formed by a photolithography process, an imprinting process, a bar-coating process, or a 3-dimensional (3D) printing process.

Therefore, the organic light emitting display panel and the organic light emitting display panel formed by the method of manufacturing according to example embodiments include the first, second, and third sub-pixel areas that respectively include the first, second, and third organic light emitting structures inclined with respect to the display substrate. Thus, light from the inclined plane may be mixed with side light that is emitted toward a side of the organic light emitting display panel. As a result, side color shift (e.g., blue color shift, yellow color shift, etc) with respect to the front side of the organic light emitting display panel may be improved in addition to the improvement of the WAD.

In addition, surface area of the first, second, and third organic light emitting structures (e.g., the blue color organic light emitting structure) may increase caused by having the inclined planes. Thus, lifetime of the light emitting diode (and the organic light emitting display panel) may be improved or increased.

### BRIEF DESCRIPTION OF THE DRAWINGS

Example embodiments can be understood in more detail from the following description taken in conjunction with the accompanying drawings, in which:

FIG. 1 is a cross-sectional view of an organic light emitting display panel according to example embodiments.

FIG. 2 is a perspective view illustrating an example of an insulation layer of the organic light emitting display panel of FIG. 1.

FIG. 3 is a perspective view illustrating another example of an insulation layer of the organic light emitting display panel of FIG. 1.

FIG. 4 is a cross-sectional view illustrating another example embodiment of an organic light emitting display panel.

FIG. 5 is a cross-sectional view illustrating another example embodiment of an organic light emitting display panel.

FIG. 6 is a cross-sectional view illustrating another example embodiment of an organic light emitting display panel.

FIG. 7 is a cross-sectional view of another organic light emitting display panel according to example embodiments.

FIG. 8 is a perspective view illustrating an example of an insulation layer of the organic light emitting display panel of FIG. 7.

FIG. 9 is another cross-sectional view illustrating an example embodiment of an organic light emitting display panel.

FIG. 10 is a flow chart illustrating a method of manufacturing an organic light emitting display panel according to example embodiments.

FIGS. 11 through 14 are cross-sectional views illustrating a method of manufacturing an example embodiment of an organic light emitting display panel according to the method of FIG. 10.

### DETAILED DESCRIPTION

Example embodiments will be described more fully hereinafter with reference to the accompanying drawings, in which various embodiments are shown.

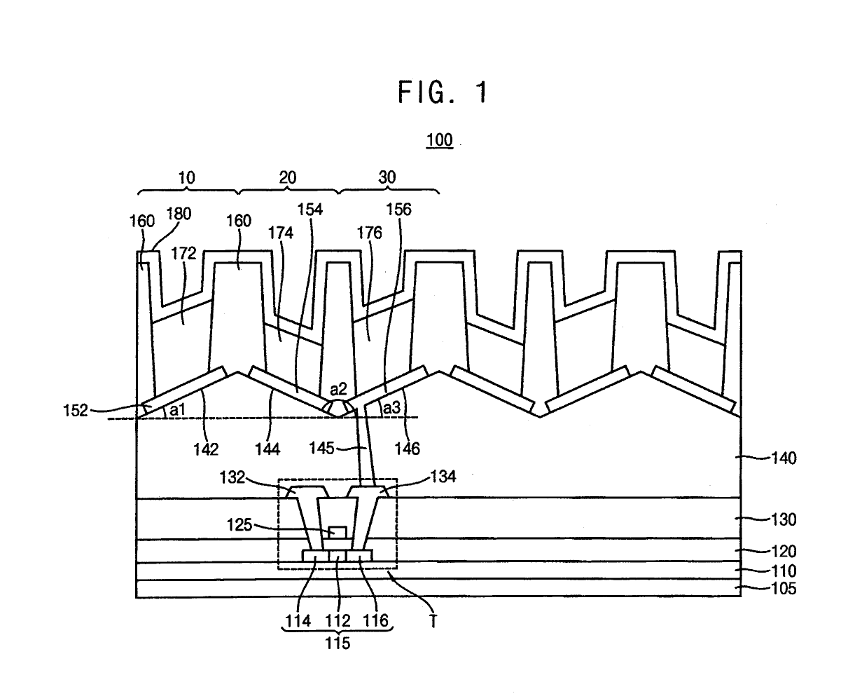

FIG. 1 is a cross-sectional view of an organic light emitting display panel according to example embodiments.

Referring to FIG. 1, the organic light emitting display panel 100 may include a display substrate 105, an insulation layer 140, a first electrode 152, a second electrode 154, a third electrode 156, a pixel defining layer 160, a first organic light emitting structure 172, a second organic light emitting structure 174, a third organic light emitting structure 176, and a common electrode 180. The insulation layer 140 may have first, second, and third planes 142, 144 and 146.

The organic light emitting display panel 100 may include a first sub-pixel area 10, a second sub-pixel area 20 adjacent to the first sub-pixel area 10, and a third sub-pixel area 30 adjacent to the second sub-pixel area 20. The first, second, and third sub-pixel areas 10, 20, and 30 may respectively include the first, second, and third organic light emitting structures 172, 174, and 176 for emitting different color lights. For example, red, green and blue color lights may be respectively emitted at the first, second and third sub-pixel areas 10, 20, and 30. A pixel area for emitting a white color light may include the first, second, and third sub-pixel areas 10, 20, and 30.

Thin film transistors (TFTs) for driving the organic light emitting display panel 100 may be located on the display substrate 105. For example, a buffer layer 110 may be located on the display substrate 105, and a thin film transistor T may be located on the buffer layer 110.

The display substrate 105 may include a transparent insulation substrate. For example, the display substrate 105 may include a glass substrate, a quartz substrate, a transparent resin substrate, etc. Alternatively, the display substrate 105 may include a flexible substrate.

The buffer lay 110 may be disposed on the display substrate 105. The buffer layer 110 may prevent or substantially prevent impurities from being diffused to the display substrate 105, and may improve flatness throughout the display substrate 105. In an example embodiment, the buffer layer 110 may include silicon oxide (SiOx), silicon nitride (SiNx) or silicon oxynitride (SiOxNy).

An active pattern 115 may be disposed on the buffer layer 110. In an example embodiment, the active pattern 115 may include polysilicon, doped polysilicon, amorphous silicon, doped amorphous silicon, and the like. In another example embodiment, the active pattern 115 may include an oxide semiconductor, such as aluminum zinc oxide (AlZnO), aluminum zinc tin oxide (AlZnSnO), gallium zinc tin oxide (GaZnSnO), indium gallium oxide (InGaO), indium gallium zinc oxide (InGaZnO), indium tin zinc oxide (InSnZnO), indium zinc oxide (InZnO), hafnium indium zinc oxide (HfInZnO), or zirconium tin oxide (ZnSnO). The active pattern 115 may include a channel region 112, a source region 114 and a drain region 116.

A gate insulation layer 120 may be disposed on the buffer layer 105 to cover the active pattern 115. In an example embodiment, the gate insulation layer may include silicon oxide, silicon nitride or an inorganic insulation material having a high dielectric permittivity.

A gate electrode 125 may be disposed on the gate insulation layer 120 to overlap the channel region 112 of the active pattern 115. In an example embodiment, the gate electrode 125 may include aluminum (Al), chromium (Cr), Nickel (Ni), Molybdenum (Mo), Tungsten (W), Magnesium (Mg) and/or their alloys. The gate electrode 125 may have a single-layered structure or a multi-layered structure.

An insulation interlayer 130 may be disposed on the gate insulation layer 120 to cover the gate electrode 125. In an example embodiment, the insulation interlayer 130 may include silicon oxide (SiOx), silicon nitride (SiNx) or silicon oxynitride (SiOxNy).

A source electrode 132 and a drain electrode 134 may be disposed on the insulation interlayer 130. The source electrode 132 and the drain electrode 134 may be formed to penetrate the insulation interlayer 130 and the gate insulation layer 120. Thus, the source electrode 132 and the drain electrode 134 may be disposed to be in contact with the source region 114 and the drain region 116, respectively. The thin film transistor T may be defined by the active pattern 115, the gate electrode 125, the source electrode 132 and the drain electrode 134. The thin film transistor T may serve as a driving transistor for applying a voltage or a current to an organic light emitting device, or may serve as a switching transistor for determining an operation of the organic light emitting display panel 100. In example embodiments, a plurality of thin film transistors may be disposed corresponding to a plurality of pixels or sub-pixels.

The insulation layer 140 may be disposed on the display substrate 105. For example, the insulation layer 140 may be disposed on the insulation interlayer 130 to cover the source electrode 132 and the drain electrode 134. The insulation layer 140 may have the first plane 142 corresponding to the first sub-pixel area 10, the second plane 144 corresponding to the second sub-pixel area 20, and the third plane 146 corresponding to the third sub-pixel area 30. At least one of the first, second and third planes 142, 144 and 146 may be inclined with respect to the display substrate 105.

In an example embodiment, the first and third planes 142 and 146 of the insulation layer 140 may be inclined in a first direction with respect to the display substrate 105, and the second plane 144 of the insulation layer 140 may be inclined in a second direction opposite to (e.g., to mirror) the first direction with respect to the display substrate 105. Light emitting diodes (e.g., a light emitting diode include a pixel electrode, an organic light emitting structure, and a common electrode) may be substantially parallel to the first, second and third planes 142, 144, and 146, respectively. For example, the first and second directions may be in a scan line direction or a data line direction. The scan line may couple (e.g., connect) a scan driving unit of the display device to the organic light emitting display panel 100, and the data line may couple a data driving unit of the display device to the organic light emitting display panel 100. Here, the first and third planes 142 and 146 may have inclined angles from about 10 degrees to about 20 degrees with respect to the display substrate 105, and the second plane 144 may have an inclined angle from about 160 degrees to about 170 degrees with respect to the display substrate 105. In other words, a first and third inclined angles a1 and a3 may have inclined angles from about 10 degrees to about 20 degrees with respect to a parallel or horizontal plane of the display substrate 105. A second inclined angle a2 may have an inclined angle from about 160 degrees to about 170 degrees with respect to the parallel plane of the display substrate 105. However, embodiments of the present disclosure are not limited thereto, and the first, second and third inclined angles a1, a2 and a3 may have the same or substantially the same angle, or may have different angles from each other.

Surface area of the organic light emitting structure arranged at the sub-pixel area may be proportional to the lifetime of the light emitting diode (e.g., the organic light emitting structure). Thus, the surface areas of the light emitting diodes (e.g., the organic light emitting structures) disposed in parallel with the first, second and third planes 142, 144, and 146 (e.g., the inclined planes) may be greater than the surface areas of the light emitting diodes disposed in parallel with the display substrate 105, so that the lifetime of the light emitting diode (and the organic light emitting display panel 100) may be improved. However, if the size of the inclined angles with respect to the display substrate 105 is larger than about 20 degrees, then front brightness of the display device may decrease. Thus, the sizes of the inclined angles with respect to the display substrate 105 may have from about 10 degrees to about 20 degrees.

In another example embodiment, each of the first, second and third planes 142, 144, and 146 may have a convex curved surface with respect to the display substrate 105.

In another example embodiment, the first, second and third planes 142, 144 and 146 may be inclined in a same direction with respect to the display substrate 105. Then, the first, second and third planes 142, 144 and 146 may have inclined angles from about 10 degrees to about 20 degrees with respect to the display substrate 105. For example, the first, second and third inclined angles a1, a2 and a3 may have inclined angles from about 10 degrees to about 20 degrees with respect to the display substrate 105. However, the shapes of the planes in the insulation layer 140 are not limited thereto. For example, one or two of the first, second and third planes may have or be inclined planes.

The insulation layer 140 may include an organic material such as a photoresist, an acryl-based resin, a polyimide-based resin, a polyamide-based resin, a siloxane-based resin, a novolak resin, an alkali-soluble resin, etc. These may be used (or utilized) alone or in a combination thereof.

In some example embodiments, the insulation layer 140 may include an inorganic material such as a silicon compound, a metal oxide, etc. For example, the insulation layer 140 may include silicon oxide, silicon nitride, silicon oxynitride, silicon oxycarbide, silicon carbon nitride, aluminum oxide, titanium oxide, tantalum oxide, magnesium oxide, zinc oxide, hafnium oxide, zirconium oxide, etc. These may be used (or utilized) alone or in a combination thereof.

The insulation layer 140 may be formed by a photolithography process, an imprinting process, a bar-coating process, or a 3-dimensional (3D) printing process. In an example embodiment, the insulation layer 140 having the first, second and third planes 142, 144 and 146 may be formed by the photolithography process using (or utilizing) a halftone mask of a slit mask. The imprinting process may form the insulation layer 140 using (or utilizing) a mold to create the first, second and third planes 142, 144 and 146. The first, second and third planes 142, 144 and 146 may be patterned by a bar-coater in bar-coating process. However, processes (or methods) to form the insulation layer 140 having the inclined planes are not limited thereto.

The first, second and third electrodes 152, 154 and 156 may be respectively disposed on the first, second and third planes 142, 144 and 146 of the insulation layer 140. The first, second and third electrodes 152, 154 and 156 may have or substantially have the same inclined angles with respect to the display substrate 105 (or the parallel plane to the display substrate 105) as the first, second and third inclined angles a1, a2 and a3. In other words, the first, second and third electrodes 152, 154 and 156 may be parallel to or substantially parallel to the first, second and third planes 142, 144 and 146.

The first, second and third electrodes 152, 154 and 156 may contact or be coupled to (e.g., connected to) the drain electrodes of the thin film transistors through contact holes penetrating the insulation layer 140. For example, the third electrode 146 may contact or be coupled to the drain electrode 134 of the thin film transistor T through a contact hole 145.

In an example embodiment, the first, second and third electrodes 152, 154 and 156 may serve as pixel electrodes corresponding to the first, second and third sub-pixel areas 10, 20 and 30, respectively. Further, the first, second and third electrodes 152, 154 and 156 may be anodes for supplying holes to the first, second and third organic light emitting structures 172, 174 and 176, respectively. The first, second and third electrodes 152, 154 and 156 may include a transparent conductive material, metal, and/or alloy. For example, the first, second and third electrodes 152, 154 and 156 may include indium tin oxide (ITO), zinc tin oxide (ZTO), indium zinc oxide (IZO), zinc oxide (ZnOx), gallium oxide (GaOx), tin oxide (SnOx), silver (Ag), aluminum (Al), platinum (Pt), gold (Au), chrome (Cr), tungsten (W), molybdenum (Mo), titanium (Ti), palladium (Pd), iridium (Ir), etc.

In an example embodiment, the first, second and third electrodes 152, 154 and 156 may be formed by a sputtering process, a vacuum evaporation process, a chemical vapor deposition (CVD) process, a pulsed laser deposition process, a printing process, an atomic layer deposition process, etc. The first, second and third electrodes 152, 154 and 156 may respectively extend to portions of non-luminescent regions adjacent to luminescent regions of the organic light emitting display device.

The pixel defining layer 160 may be disposed on the insulation layer 140. The pixel defining layer 160 may define the first, second and third sub-pixel areas 10, 20 and 30. In an example embodiment, the pixel defining layer 160 may be formed on a portion of the insulation layer 140 and on a portion of the first, second and third electrodes 152, 154 and 156. A surface of the pixel defining layer 160 may be substantially parallel to the display substrate 105. Portions of the first, second and third electrodes 152, 154 and 156 exposed by the pixel defining layer 160 may correspond to the luminescent regions of the first, second and third sub-pixel areas, respectively.

The pixel defining layer 160 may include an organic material, such as, for example, polyacryl-based resin, epoxy-based resin, phenol-based resin, polyamide-based resin, polyimide-based resin, unsaturated polyester-based resin, polyphenylene-based resin, poly(phenylenesulfide)-based resin, benzocyclobutene (BCB), etc. In some example embodiments, the pixel defining layer 160 may include an inorganic material such as silicon oxide, silicon nitride, silicon oxynitride, etc. In an example embodiment, the pixel defining layer 160 may be formed by a photolithography process using or utilizing a mask.

The first, second and third organic light emitting structures 172, 174 and 176 may be respectively disposed on the first, second and third electrodes 152, 154 and 156. The first, second and third organic light emitting structures 172, 174 and 176 may be parallel to or substantially parallel to the first, second and third planes 142, 144 and 146, respectively. For example, the first organic light emitting structure 172 may have uniform thickness, and a surface of the first organic light emitting structure 172 may be parallel to the first plane 142. The first, second and third organic light emitting structures 172, 174 and 176 may include first, second and third emission layers (EML), respectively. The first, second and third light emitting layers may respectively generate different colors of light. For example, the first organic light emitting structure 172 may include a red color light emission layer, the second organic light emitting structure 174 may include a green color light emission layer, and the third organic light emitting structure 176 may include a blue color light emission layer. The first, second and third emission layers may be formed by a spin coating process, a roll printing process, a nozzle printing process, an inkjet printing process, a transfer process using (or utilizing) a donor substrate, etc.

The first, second and third organic light emitting structures 172, 174 and 176 may substantially have the same inclined angles with respect to the display substrate 105 as the first, second and third inclined angles a1, a2 and a3. Thus, the light may be emitted from inclined planes of the first, second and third organic light emitting structures 172, 174 and 176, so that light emitted from the inclined planes may be mixed with side light that is emitted toward a side of the organic light emitting display panel 100. In this case, the mixed light may be controlled by adjusting the inclined angles a1, a2 and a3. As a result, the side color shift (e.g., blue color shift, yellow color shift, etc) with respect to the front (e.g., front side or front surface) of the organic light emitting display panel 100 may be improved in addition to the improvement of the WAD.

The first, second and third organic light emitting structures 172, 174 and 176 may include at least one of a hole injection layer (HIL) and a hole transmission layer (HTL) between the first, second and third electrodes 152, 154 and 156, and the first, second and third emission layers, respectively. Further, the first, second and third organic light emitting structures 172, 174 and 176 may include at least one of an electron injection layer (EIL) and an electron transmission layer (ETL) between the first, second and third emission layers and the common electrode 180, respectively.

The common electrode 180 may be disposed on the first, second and third organic light emitting structures 172, 174 and 176. The common electrode 180 may have a thickness that is substantially uniform on the first, second and third light emitting structures 172, 174 and 176 and the pixel defining layer 160. In an example embodiment, the common electrode 180 may extend from the luminescent regions to the non-luminescent regions. In another example embodiment, the common electrode 180 may be formed only in the luminescent regions.

The common electrode 180 may include a transparent conductive material such as indium tin oxide (ITO), zinc tin oxide (ZTO), indium zinc oxide (IZO), zinc oxide (ZnOx), gallium oxide (GaOx), tin oxide (SnOx), etc. These materials may be used (or utilized) alone or in combination thereof. In an example embodiment, the common electrode 180 may be a cathode for supplying electrons to the first, second and third organic light emitting structures 172, 174 and 176. The common electrode 180 may be formed by a sputtering process, a vacuum evaporation process, a CVD process, a pulsed laser deposition process, a printing process, an atomic layer deposition process, etc.

In an embodiment, the organic light emitting display panel 100 may further include an encapsulation substrate to cover the common electrode 180.

As described above, the organic light emitting display panel 100 in FIG. 1 may include the first, second and third sub-pixel areas 10, 20 and 30 that respectively include the first, second and third organic light emitting structures 172, 174 and 176 which are inclined with respect to the display substrate 105. Thus, light emitted from the inclined plane may be mixed with side light that is emitted toward a side (e.g., left or right side) of the organic light emitting display panel 100. As a result, side color shift (e.g., blue color shift, yellow color shift, etc) with respect to the front (e.g., front side or front surface) of the organic light emitting display panel may be improved in addition to the improvement of the WAD.

In addition, surface area of the first, second and third organic light emitting structures 172, 174 and 176 (e.g., the blue color organic light emitting structure) may be increased due to the inclined planes. Thus, the lifetime of the organic light emitting structures (and the organic light emitting display panel 100) may be improved (e.g., increased).

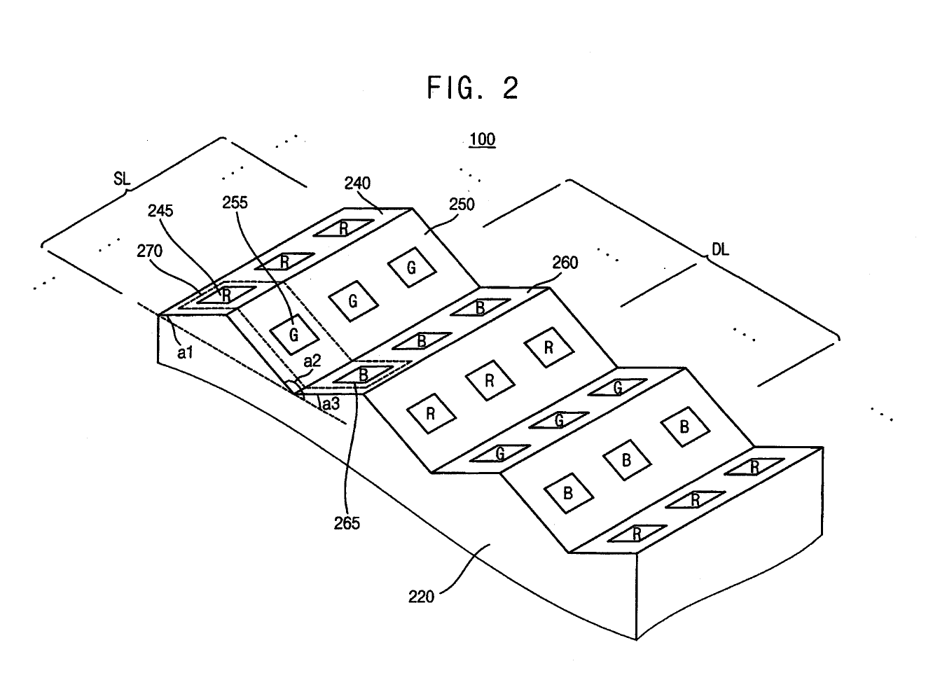

FIG. 2 is a perspective view illustrating an example of an insulation layer of the organic light emitting display panel of FIG. 1.

Referring to FIG. 2, the organic light emitting display panel 100 may include a plurality of sub-pixel areas 245, 255 and 265 (e.g., first, second and third sub-pixel areas) located on an insulation layer 220. The insulation layer 320 may have first, second and third planes 240, 250 and 260.

The first, second and third planes 240, 250 and 260 may be inclined with respect to the display substrate. The first plane 240 may have a first inclined angle al with respect to the display substrate. The second plane 250 may have a second inclined angle a2 with respect to the display substrate. The third plane 260 may have a third inclined angle a3 with respect to the display substrate. As illustrated in FIG. 2, in an example embodiment, the first, second and third planes 240, 250 and 260 may be arranged along a line that is substantially parallel to data lines DL.

A pixel electrode, an organic light emitting structure, and a common electrode (e.g., an upper structure) may have inclined angles with respect to the display substrate. Thus, light from the inclined plane may be mixed with side light that is emitted toward a side of the organic light emitting display panel.

A pixel area 270 may include the first, second and third sub-pixels 245, 255 and 265. In an example embodiment, a red color light may be emitted from the first sub-pixel area 245, a green color light may be emitted from the second sub-pixel area 255, and a blue color light may be emitted from the third sub-pixel area 265. A plurality of sub-pixel areas for emitting the red color light may be arranged on the first plane 240 in a row. A plurality of sub-pixel areas for emitting the green color light may be arranged on the second plane 250 in a row. A plurality of sub-pixel areas for emitting the blue color light may be arranged on the third plane 260 in a row. However, the color of light emitted from the sub-pixel areas on the first, second and third planes 240, 250 and 260 are not limited thereto. For example, red sub-pixel areas, green sub-pixel areas and blue sub-pixel areas may be alternately arranged on the first plane 240.

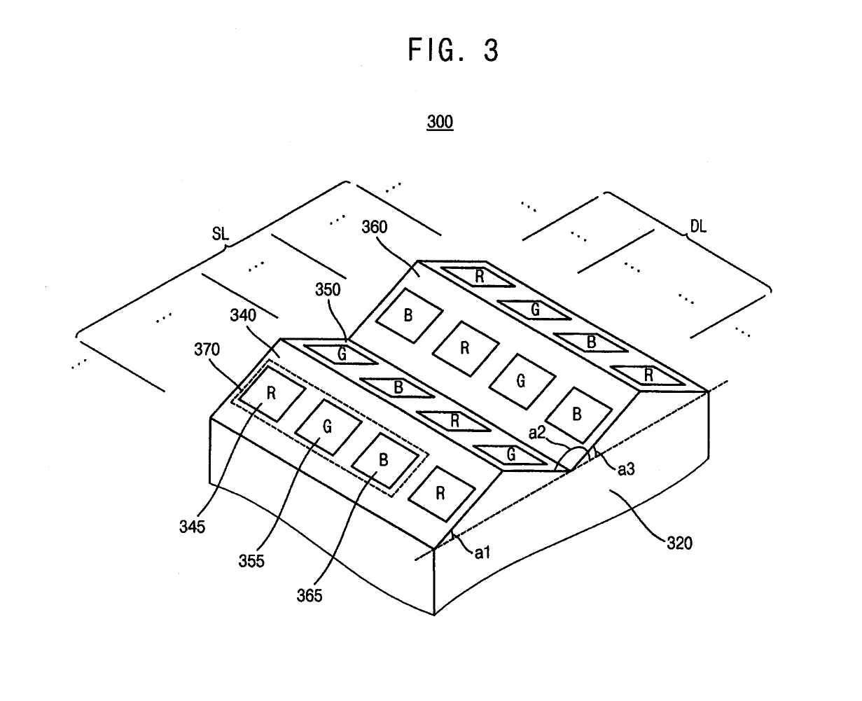

FIG. 3 is a perspective view illustrating another example of an insulation layer of the organic light emitting display panel of FIG. 1.

Referring to FIG. 3, the organic light emitting display panel 300 may include a plurality of sub-pixel areas 345, 355 and 365 (e.g., first, second and third sub-pixel areas) located on an insulation layer 320. The insulation layer 320 may have first, second and third planes 340, 350 and 360.

The first, second and third planes 340, 350 and 360 may be inclined with respect to the display substrate. The first plane 340 may have a first inclined angle al with respect to the display substrate. The second plane 350 may have a second inclined angle a2 with respect to the display substrate. The third plane 360 may have a third inclined angle a3 with respect to the display substrate. As illustrated in FIG. 3, in an example embodiment, the first, second and third planes 340, 350 and 360 may be arranged along a line that is substantially parallel to scan lines SL. The scan lines SL may be orthogonal or substantially orthogonal to the data lines DL.

A pixel electrode, an organic light emitting structure, and a common electrode (e.g., an upper structure) may have inclined angles with respect to the display substrate. Thus, light from the inclined plane may be mixed with side light that is emitted toward a side of the organic light emitting display panel.

A pixel area may include the first, second and third sub-pixels 345, 355 and 365. In an example embodiment, a red color light may be emitted from the first sub-pixel area 345, a green color light may be emitted from the second sub-pixel area 355, and a blue color light may be emitted from the third sub-pixel area 365. Red sub-pixel areas, green sub-pixel areas and blue sub-pixel areas may be alternately arranged on the first plane 340. Red sub-pixel areas, green sub-pixel areas and blue sub-pixel areas may be alternately arranged on the second and third planes 350 and 360. However, the color of light emitted from the sub-pixel areas on the first, second and third planes 240, 250 and 260 are not limited thereto.

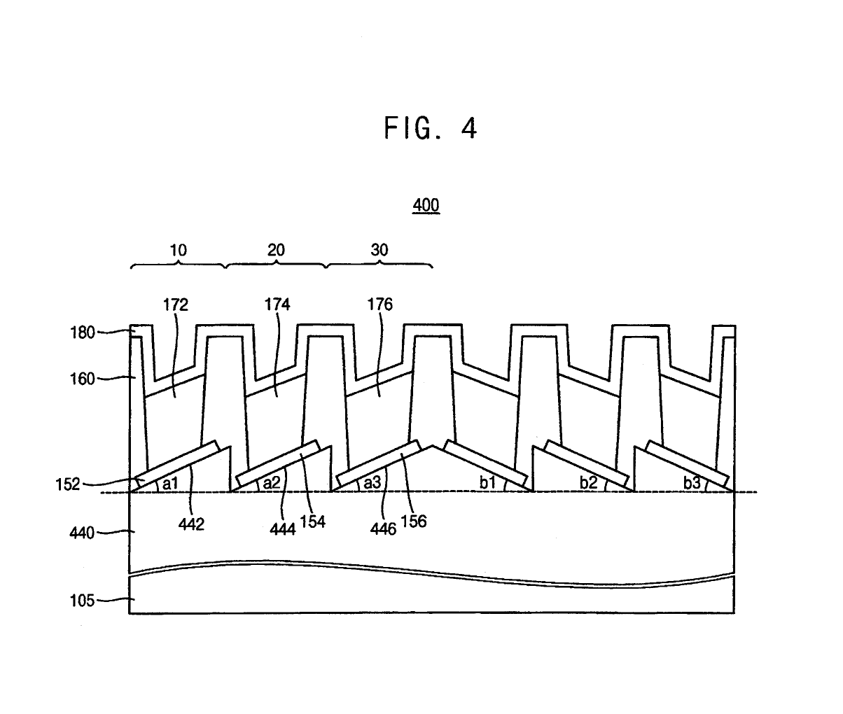

FIG. 4 is a cross-sectional view illustrating another example embodiment of an organic light emitting display panel.

Referring to FIG. 4, the organic light emitting display panel 400 may include a display substrate 105, an insulation layer 440, first, second and third electrodes 152, 154 and 156, a pixel defining layer 160, first, second, and third organic light emitting structures 172, 174 and 176, and a common electrode 180. The insulation layer 440 may have first, second and third planes 442, 444 and 446.

The organic light emitting display panel 400 may include a first sub-pixel area 10, a second sub-pixel area 20 adjacent to the first sub-pixel area 10, and a third sub-pixel area 30 adjacent to the second sub-pixel area 20. The first, second and third sub-pixel areas 10, 20 and 30 may respectively include the first, second and third organic light emitting structures 172, 174 and 176 for emitting different color lights. A first pixel area may be comprised of the first, second and third sub-pixel areas 10, 20 and 30.

The insulation layer 440 may have a plurality of planes corresponding to the sub-pixel areas. The insulation layer 440 may include the first plane 442 corresponding to the first sub-pixel area 10, the second plane 444 corresponding to the second sub-pixel area 20, and the third plane 446 corresponding to the third sub-pixel area 30.

The first plane 442 may have a first inclined angle al with respect to the display substrate 105, the second plane 444 may have a second inclined angle a2 with respect to the display substrate 105, and the third plane 446 may have a third inclined angle a3 with respect to the display device 105. In an example embodiment, the first, second and third planes 442, 444 and 446 may be inclined in a same direction with respect to the display substrate 105. Thus, light emitting diodes may emit light toward the same direction. Further, the first, second and third planes 442, 444 and 446 may have inclined angles from about 10 degrees to about 20 degrees with respect to the display substrate 105. The first, second and third inclined angles a1, a2 and a3 may have the same or substantially the same angle, or may have different angles from each other.

In an example embodiment, the insulation layer 440 may have inclined planes that are inclined in an opposite direction to the first, second and third planes 442, 444 and 446. The inclined planes may correspond to a second pixel area adjacent to the first pixel area. Thus, inclined angles b1, b2 and b3 corresponding to the inclined planes in the second pixel area may have opposite angles from the first, second and third inclined angles a1, a2 and a3 with respect to the display substrate 105. For example, the inclined angles b1, b2 and b3 may have inclined angles from about 160 degrees to about 170 degrees with respect to the display substrate 105.

The first, second and third electrodes 152, 154 and 156 may be respectively disposed on the first, second and third planes 442, 444 and 446 of the insulation layer 440. The first, second and third electrodes 152, 154 and 156 may have the same or substantially the same inclined angles with respect to the display substrate 105 (or the parallel or horizontal plane of the display substrate 105) as the first, second and third inclined angles a1, a2 and a3. In other words, the first, second and third electrodes 152, 154 and 156 may be parallel or substantially parallel to the first, second and third planes 442, 444 and 446.

The first, second and third organic light emitting structures 172, 174 and 176 may be respectively disposed on the first, second and third electrodes 152, 154 and 156. The first, second and third organic light emitting structures 172, 174 and 176 may respectively include a red color light emission layer, a green color light emission layer and a blue color light emission layer to emit a red color light, a green color light and a blue color light from the first, second and third sub-pixel areas 10, 20 and 30, respectively.

The common electrode 180 may be disposed on the first, second and third organic light emitting structures 172, 174 and 176. In an example embodiment, the common electrode 180 may have a thickness that is substantially uniform on the first, second and third light emitting structures 172, 174 and 176, and the pixel defining layer 160.

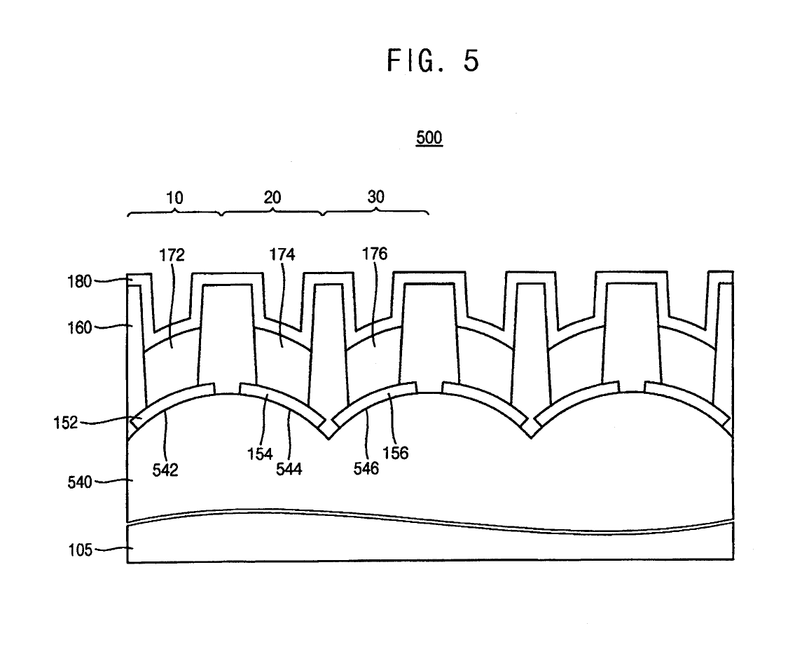

FIG. 5 is a cross-sectional view illustrating another example embodiment of an organic light emitting display panel.

Referring to FIG. 5, the organic light emitting display panel 500 may include a display substrate 105, an insulation layer 540, first, second and third electrodes 152, 154 and 156, a pixel defining layer 160, first, second, and third organic light emitting structures 172, 174 and 176, and a common electrode 180. The insulation layer 540 may have first, second and third planes 542, 544 and 546.

The organic light emitting display panel 500 may include a first sub-pixel area 10, a second sub-pixel area 20 adjacent to the first sub-pixel area 10, and a third sub-pixel area 30 adjacent to the second sub-pixel area 20. The first, second and third sub-pixel areas 10, 20 and 30 may respectively include the first, second and third organic light emitting structures 172, 174 and 176 for emitting different color lights.

The insulation layer 540 may have the first plane 542 corresponding to the first sub-pixel area 10, the second plane 544 corresponding to the second sub-pixel area 20, and the third plane 546 corresponding to the third sub-pixel area 30.

In an example embodiment, the first and third planes 542 and 546 of the insulation layer 540 may be inclined in a first direction with respect to the display substrate 105, and the second plane 544 of the insulation layer 540 may be inclined in a second direction opposite to the first direction with respect to the display substrate 105. Light emitting diodes (e.g., a light emitting diode including a pixel electrode, an organic light emitting structure, and a common electrode) may be parallel or substantially parallel to the first, second and third planes 542, 544 and 546, respectively.

In an example embodiment, as illustrated in FIG. 5, each of the first, second and third planes 542, 544 and 546 may have a convex curved surface with respect to the display substrate 105. The convex curved surfaces may be formed by the insulation layer forming processes described above.

The first, second and third electrodes 542, 544 and 546, the first, second, and third organic light emitting structures 172, 174 and 176, and the common electrode 180 may have convex curved surfaces like or matching the convex curved surfaces of the first, second and third planes 542, 544 and 546, respectively.

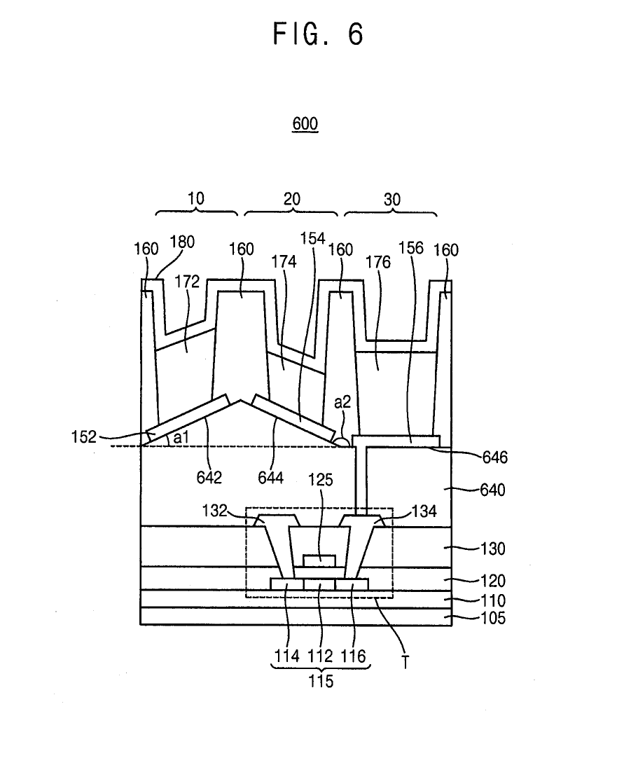

FIG. 6 is a cross-sectional view illustrating another example embodiment of an organic light emitting display panel.

Referring to FIG. 6, the organic light emitting display panel 600 may include a display substrate 105, an insulation layer 640, first, second and third electrodes 152, 154 and 156, a pixel defining layer 160, first, second, and third organic light emitting structures 172, 174 and 176, and a common electrode 180. The insulation layer 640 may have first, second and third planes 642, 644 and 646.

In an example embodiment, the insulation layer 640 may have the first plane 642 corresponding to the first sub-pixel area 10, the second plane 644 corresponding to the second sub-pixel area 20, and a third plane 646 corresponding to the third sub-pixel area 30. The first plane 642 may have a first inclined angle al with respect to the display substrate 105, the second plane 644 may have a second inclined angle a2 with respect to the display substrate 105, and the third plane 646 may be parallel or substantially parallel to the display substrate 105. In other words, at least one of the first, second and third sub-pixel areas may have an inclined plane. For example, when a blue color light, a green color light and a red color light is respectively emitted from the first, second and third sub-pixel areas, only the red color light may be emitted in a vertical (e.g., perpendicular or normal) direction from the display substrate 105. However, the colors of light and emitting directions are not limited thereto.

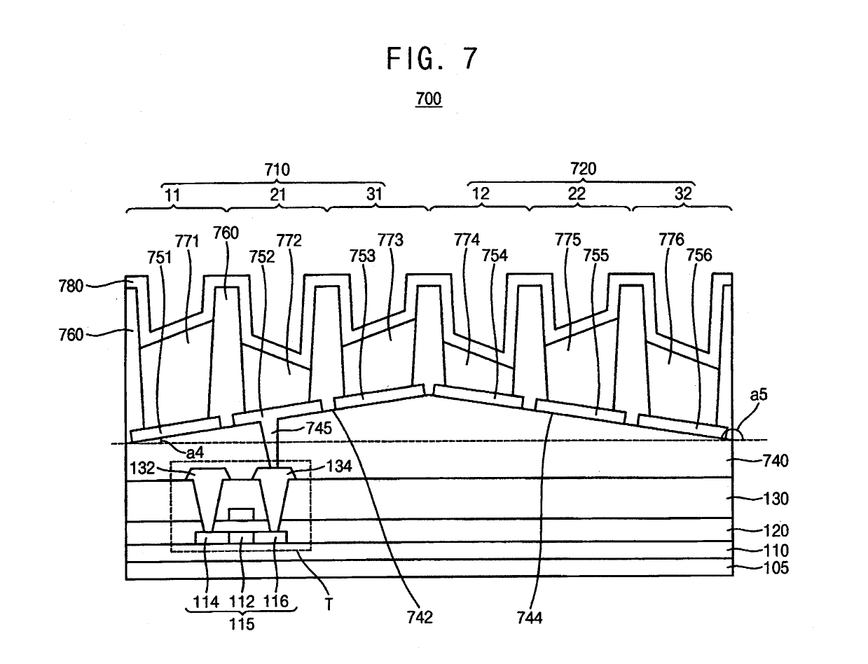

FIG. 7 is a cross-sectional view of another organic light emitting display panel according to example embodiments.

Referring to FIG. 7, the organic light emitting display panel 700 may include a display substrate 105, an insulation layer 740, first to sixth electrodes 751, 752, 753, 754, 755 and 756, a pixel defining layer 760, first to sixth organic light emitting structures 771, 772, 773, 774, 775 and 776, and a common electrode 780. The insulation layer 740 may include a first common plane 742 and a second common plane 744.

The organic light emitting display panel 700 may include a first pixel area 710 including first, second and third sub-pixel areas 11, 21 and 31, and a second pixel area 720 including fourth, fifth and sixth sub-pixel areas 12, 22 and 32. The second pixel area 720 may be arranged adjacent to the first pixel area 710. The first common plane 742 may be inclined in a first direction with respect to the display substrate 105, and the second common plane 744 may be inclined in a second direction opposite to (e.g., to mirror) the first direction with respect to the display substrate 105.

Thin film transistors (TFTs) for driving the first and second pixel areas 710 and 720 may be disposed on the display substrate 105. For example, a buffer layer 110 may be disposed on the display substrate 105, and a thin film transistor T may be disposed on the buffer layer 110.

The thin film transistor T may include an active pattern 115 including a channel region 112, a source region 114, and a drain region 116. The thin film transistor T may also include a gate insulation layer 125, an insulation interlayer 130, a source electrode 132, and a drain electrode 134. Since the display substrate 105, the buffer layer 110 and the thin film transistor T are substantially the same as those described above with reference to FIG. 1, duplicated descriptions thereof may not have been repeated.

The insulation layer 740 may be disposed on the display substrate 105. In one embodiment, the insulation layer 740 may be disposed on the insulation interlayer 130 to cover the source electrode 132 and the drain electrode 134. The first common plane 742 corresponding to the first pixel area 710 may have a first inclined angle a4 with respect to the display substrate 105. The second common plane 744 corresponding to the second pixel area 720 may have a second inclined angle a5 with respect to the display substrate 105. Thus, the first, second and third sub-pixel areas 11, 21 and 31 included in the first pixel area 710 may be formed on the first common plane 742, and the fourth, fifth and sixth sub-pixel areas 12, 22 and 32 included in the second pixel area 720 may be formed on the second common plane 744. In an example embodiment, each of the first and second common planes 742 and 744 may have a convex curved surface. However, embodiments of the present disclosure are not limited thereto.

In an example embodiment, the first common plane 742 may be inclined in a first direction with respect to the display substrate 105, and the second common plane 744 may be inclined in a second direction opposite to (e.g., to mirror) the first direction with respect to the display substrate 105. For example, the first and second common planes 742 and 744 may be arranged along a line in a scan line direction or a data line direction. Here, the first common plane 742 may have the first inclined angle a4 from about 10 degrees to about 20 degrees with respect to the display substrate 105, and the second common plane 744 may have the second inclined angle a5 from about 160 degrees to about 170 degrees with respect to the display substrate 105. However, the directions of the first and second planes 742 and 744 are not limited thereto.

In an example embodiment, the first and second common plane 742 and 744 of the insulation layer 740 may be formed by a photolithography process, an imprinting process, a bar-coating process, or a 3-dimensional (3D) printing process. Since the insulation layer is described above with reference to FIG. 1, duplicate descriptions thereof may not have been repeated.

The first, second and third electrodes 751, 752 and 753 may be disposed on the first common plane 742 to respectively correspond to the first, second and third sub-pixel areas 11, 21 and 31. The fourth, fifth and sixth electrodes 754, 755 and 756 may be disposed on the second common plane 744 to respectively correspond to the fourth, fifth and sixth sub-pixel areas 12, 22 and 32. The first, second and third electrodes 751, 752 and 753 may be parallel or substantially parallel to the first common plane 742, and the fourth, fifth and sixth electrodes 754, 755 and 756 may be parallel or substantially parallel to the second common plane 744.

The first to sixth electrodes 751, 752, 753, 754, 755, and 756 may serve as pixel electrodes corresponding to the first to sixth sub-pixel areas 11, 21, 31, 12, 22, and 32, respectively. Further, the first to sixth electrodes 751, 752, 753, 754, 755 and 756 may be anodes for supplying holes to the first to sixth organic light emitting structures 771, 772, 773, 774, 775 and 776, respectively.

The pixel defining layer 760 may be disposed on the insulation layer 740. The pixel defining layer 760 may define the first to sixth sub-pixel areas 11, 21, 31, 12, 22, and 32. In an example embodiment, the pixel defining layer 760 may be formed on a portion of the insulation layer 740 and on a portion of the first to sixth electrodes 751, 752, 753, 754, 755 and 756. Portions of the first to sixth electrodes 751, 752, 753, 754, 755 and 756 exposed by the pixel defining layer 760 may correspond to the luminescent regions of the first to sixth sub-pixel areas 11, 21, 31, 12, 22 and 32, respectively.

The first, second and third organic light emitting structures 771, 772 and 773 may be respectively disposed on the first, second and third electrodes 751, 752 and 753. The first, second and third organic light emitting structures 771, 772 and 773 may be parallel or substantially parallel to the first common plane 742. The first, second and third organic light emitting structures 771, 772 and 773 may include first, second and third emission layers (EML), respectively. The first, second and third light emitting layers may respectively generate different colors of light. For example, the first organic light emitting structure 771 may include a red color light emission layer, the second organic light emitting structure 772 may include a green color light emission layer, and the third organic light emitting structure 773 may include a blue color light emission layer.

The fourth, fifth and sixth organic light emitting structures 774, 775 and 776 may be respectively disposed on the fourth, fifth and sixth electrodes 754, 755 and 756. The fourth, fifth and sixth organic light emitting structures 774, 775 and 776 may be parallel or substantially parallel to the second common plane 744. The fourth, fifth and sixth organic light emitting structures 774, 775 and 776 may include fourth, fifth and sixth emission layers (EML), respectively. The fourth, fifth and sixth light emitting layers may respectively generate different colors of light. For example, the fourth organic light emitting structure 774 may include the red color light emission layer, the fifth organic light emitting structure 775 may include the green color light emission layer, and the sixth organic light emitting structure 776 may include the blue color light emission layer.

The common electrode 780 may be disposed on the first to sixth organic light emitting structures 771, 772, 773, 774, 775 and 776. In an example embodiment, the common electrode 180 may have a thickness that is substantially uniform on the first to sixth organic light emitting structures 771, 772, 773, 774, 775 and 776, and the pixel defining layer 760.

Since the pixel electrodes, the organic light emitting structures, and the common electrode are described above with reference to FIG. 1, duplicated descriptions may not have been repeated.

As described above, the organic light emitting display panel 700 in FIG. 7 may include the first and second pixel areas 710 and 720 on the inclined planes (e.g., first and second common planes 742 and 744), respectively. Thus, light from the inclined plane may be mixed with side light that is emitted toward a side of the organic light emitting display panel 700. As a result, side color shift (e.g., blue color shift, yellow color shift, etc) with respect to the front side of the organic light emitting display panel 700 may be improved in addition to the improvement of the WAD.

In addition, the surface area of the first to sixth organic light emitting structures 771, 772, 773, 774, 775 and 776 (e.g., the blue color organic light emitting structure) may be increased due to the inclined planes. Thus, a lifetime of the organic light emitting structures (and the organic light emitting display panel 700) may be improved (e.g., increased).

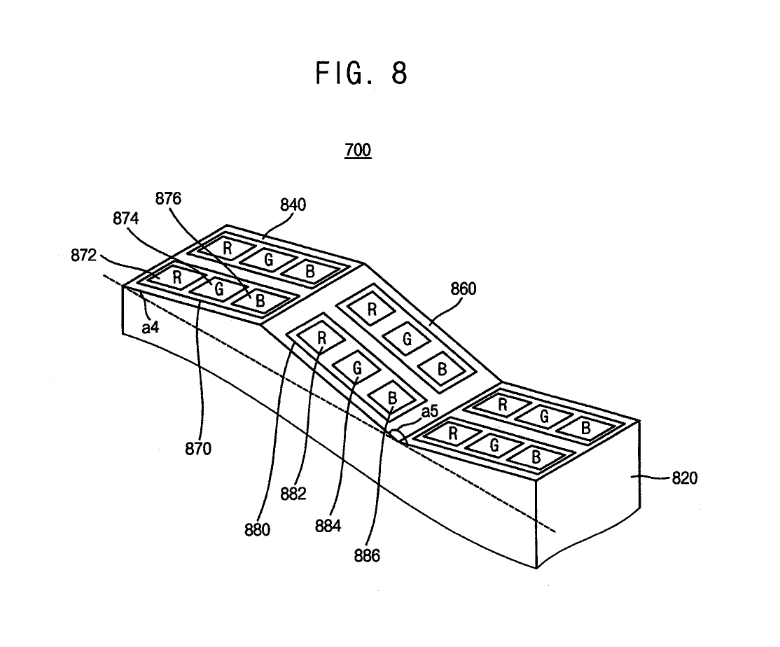

FIG. 8 is a perspective view illustrating an example of an insulation layer of the organic light emitting display panel of FIG. 7.

Referring to FIG. 8, the organic light emitting display panel 700 may include a plurality of pixel areas 870 and 880 on the insulation layer 820.

The insulation layer 820 may include a first common plane 840 corresponding to the first pixel area 870. The first common plane 840 may have a first common inclined angle a4 with respect to a display substrate. In an example embodiment, the first pixel area 870 may include a first sub-pixel area 872, a second sub-pixel area 874 and a third sub-pixel area 876. In an example embodiment, a red color light may be emitted from the first sub-pixel area 872, a green color light may be emitted from the second sub-pixel area 874, and a blue color light may be emitted from the third sub-pixel area 876. Also, the second common plane 860 may have a second common inclined angle a5 with respect to a display substrate. In an example embodiment, the second pixel area 870 may include a fourth sub-pixel area 882, a fifth sub-pixel area 884, and a sixth sub-pixel area 886. In an example embodiment, the red color light may be emitted from the fourth sub-pixel area 882, the green color light may be emitted from the fifth sub-pixel area 884, and the blue color light may be emitted from the sixth sub-pixel area 886. The first common plane 840 may be inclined in a first direction with respect to the display substrate, and the second common plane 860 may be inclined in a second direction opposite to (e.g., to mirror) the first direction with respect to the display substrate.

Pixel structures that are substantially the same as or similar to the first pixel area 870 may be arranged on the first common plane 840. Pixel structures that are substantially the same as or similar to the second pixel area 880 may be arranged on the second common plane 860. The organic light emitting display panel 700 may include an insulation layer structure where the first and second common planes 840 and 860 are alternately formed.

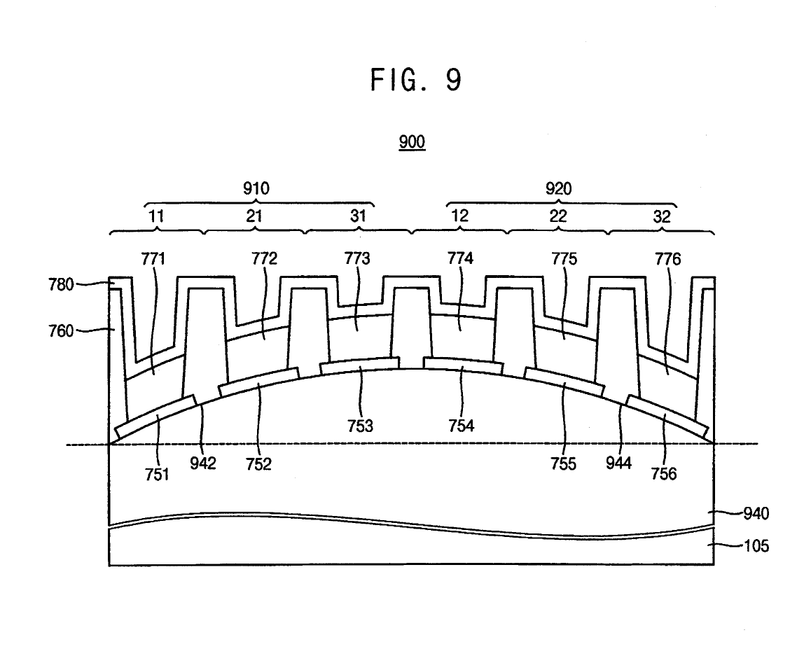

FIG. 9 is a cross-sectional view illustrating another example embodiment of an organic light emitting display panel.

Referring to FIG. 9, the organic light emitting display panel 900 may include a display substrate 105, an insulation layer 940, first to sixth electrodes 751, 752, 753, 754, 755 and 756, a pixel defining layer 760, first to sixth organic light emitting structures 771, 772, 773, 774, 775 and 776, and a common electrode 780. The insulation layer 940 may include a first common plane 942 and a second common plane 944.

The organic light emitting display panel 900 may include a first pixel area 910 including first, second and third sub-pixel areas 11, 21 and 31, and a second pixel area 920 including fourth, fifth and sixth sub-pixel areas 12, 22 and 32. The second pixel area 920 may be arranged adjacent to the first pixel area 910. The first common plane 942 may be inclined in a first direction with respect to the display substrate 105, and the second common plane 944 may be inclined in a second direction opposite to (e.g., to mirror) the first direction with respect to the display substrate 105.

As illustrated in FIG. 9, each of the first and second common planes 942 and 944 may have a convex curved surface with respect to the display substrate 105. Thus, the first to sixth electrodes 751, 752, 753, 754, 755 and 756, the first to sixth organic light emitting structures 771, 772, 773, 774, 775 and 776, and the common electrode 780 may have respective convex curved surfaces like the convex curved surfaces of the first and second common planes 942 and 944.

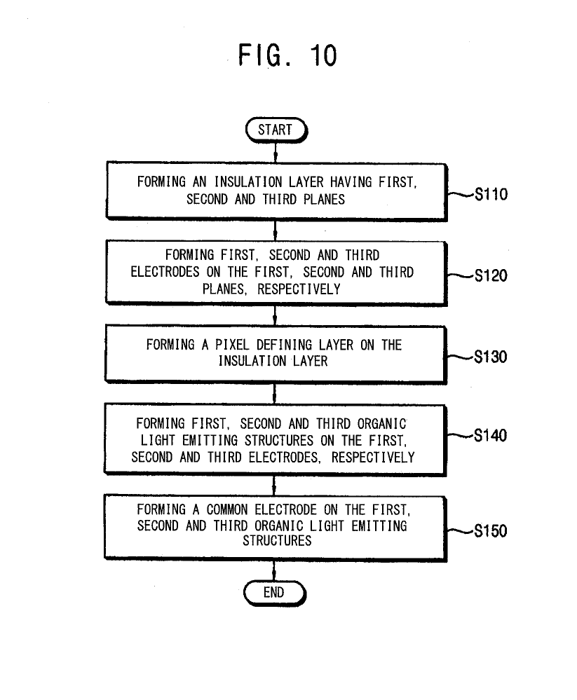

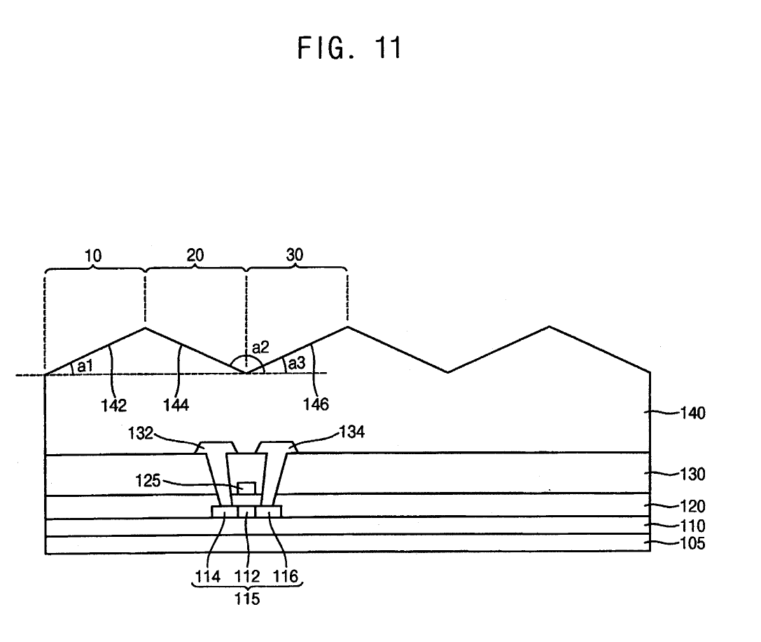

FIG. 10 is a flow chart illustrating a method of manufacturing an organic light emitting display panel according to example embodiments, and FIGS. 11 through 14 are cross-sectional views illustrating a method of manufacturing an example embodiment of an organic light emitting display panel according to the method of FIG. 10.

Referring to FIGS. 10 through 14, the method of manufacturing an organic light emitting display panel may include forming an insulation layer 140 including a first plane 142, a second plane 144 and a third plane 146 on a display substrate 105 (S110). Forming first, second and third electrodes 152, 154 and 156 on the insulation layer 140 (S120). Forming a pixel defining layer 160 on the insulation layer 140 (S130). Forming first, second and third organic light emitting structures 172, 174 and 176 on the first, second and third electrodes 152, 154 and 156, respectively (S140). Forming a common electrode 180 on the first, second and third organic light emitting structures 172, 174 and 176 (S150). At least one of the first, second and third planes 142, 144 and 146 may be inclined with respect to the display substrate 105.

As illustrated in FIG. 11, the insulation layer 140 including the first plane 142 corresponding to a first sub-pixel area 10, the second plane 144 corresponding to a second sub-pixel area 20, and the third plane 146 corresponding to a third sub-pixel area 30 may be formed on the display substrate 105 (S110).

The display substrate 105 may include a transparent insulation substrate. For example, the first substrate 105 may include a glass substrate, a quartz substrate, a transparent resin substrate, etc.

A buffer layer 110 may be formed on the display substrate 105. The buffer layer 110 may prevent or substantially prevent impurities from being diffused to the display substrate 105, and may improve flatness throughout the display substrate 105. In an example embodiment, the buffer layer 110 may include silicon oxide (SiOx), silicon nitride (SiNx), or silicon oxynitride (SiOxNy).

A thin film transistor T may be formed on the buffer layer 110. In an example embodiment, the thin film transistor T may serve as a driving transistor for applying a voltage or a current to an organic light emitting device, or may serve as a switching transistor for determining an operation of the organic light emitting display panel.

The thin film transistor T may include an active pattern 115 having a channel region 112, a source region 114, and a drain region 116, a gate insulation layer 125, an insulation interlayer 130, a source electrode 132, and a drain electrode 134. The active pattern 115, the gate insulation layer 125, the insulation interlayer 130, the source electrode 132, and the drain electrode 134 may be formed to substantially define the thin film transistor T.

The insulation layer 140 having the first, second and third planes 142, 144 and 146 may be formed on the display substrate (e.g., on the insulation interlayer 130). The first, second and third planes 142, 144 and 146 may be inclined with respect to the display substrate 105. The first, second and third planes 142, 144 and 146 may respectively have first, second and third inclined angles a1, a2 and a3 with respect to the display substrate 105.

In an example embodiment, the first and third planes 142 and 146 of the insulation layer 140 may be inclined in a first direction with respect to the display substrate 105, and the second plane 144 of the insulation layer 140 may be inclined in a second direction opposite to (e.g., to mirror) the first direction with respect to the display substrate 105. Here, the first and third planes 142 and 146 may have inclined angles from about 10 degrees to about 20 degrees with respect to the display substrate 105, and the second plane 144 may have an inclined angle from about 160 degrees to about 170 degrees with respect to the display substrate 105. In other words, a first and third inclined angles a1 and a3 may have inclined angles from about 10 degrees to about 20 degrees with respect to a parallel plane of the display substrate 105. A second inclined angle a2 may have an inclined angle from about 160 degrees to about 170 degrees with respect to the parallel plane of the display substrate 105. The first, second and third inclined angles a1, a2 and a3 may have the same or substantially the same angle, or may have angles different from each other. In an example embodiment, each of the first, second and third planes 142 144 and 146 may have a convex curved surface.

In some example embodiments, the first, second and third planes 142, 144 and 146 may be inclined in a same direction with respect to the display substrate 105. For example, the first, second and third inclined angles a1, a2 and a3 may have inclined angles from about 10 degrees to about 20 degrees with respect to the display substrate 105. Since these are examples only, however, shapes of the planes included in the insulation layer 140 are not limited thereto. For example, one or two of the first, second and third planes may have inclined plane.

The insulation layer 140 may include an organic material such as a photoresist, etc., or an inorganic material such as a silicon compound, a metal oxide, etc. The insulation layer 140 may be formed by a photolithography process, an imprinting process, a bar-coating process, or a 3-dimensional (3D) printing process. In an example embodiment, the insulation layer 140 including the first, second and third planes 142, 144 and 146 may be formed by the photolithography process using (or utilizing) a halftone mask of a slit mask. However, the processes (or methods) of forming the insulation layer 140 having the inclined planes are not limited thereto.

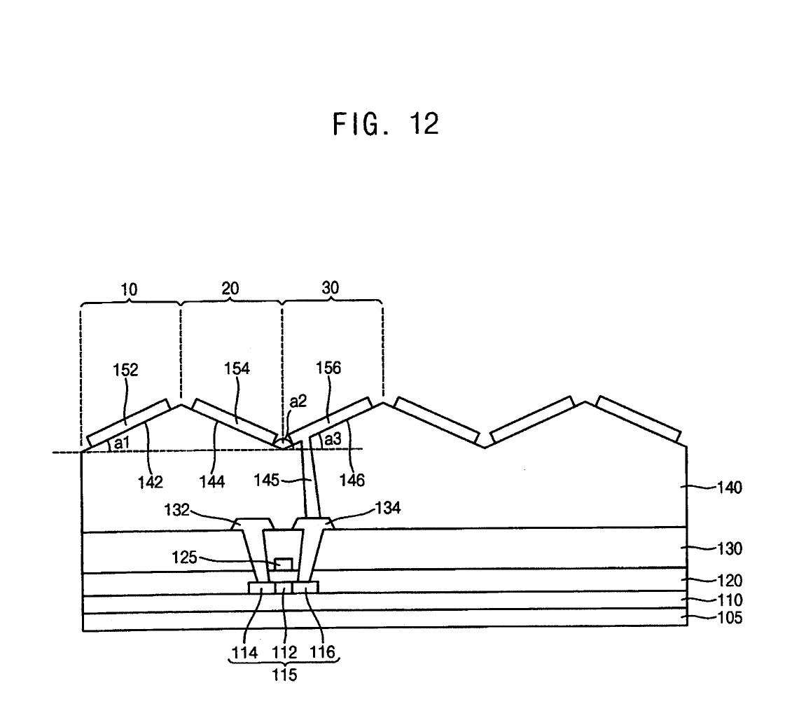

As illustrated in FIG. 12, the first, second and third electrodes 152, 154 and 156 may be respectively formed on the first, second and third planes 142, 144 and 146 of the insulation layer 140 (S120).

The first, second and third electrodes 152, 154 and 156 may have the same or substantially the same inclined angles with respect to the display substrate 105 (or the plane parallel to the display substrate 105) as the first, second and third inclined angles a1, a2 and a3. The first, second and third electrodes 152, 154 and 156 may contact (e.g., be coupled or connected to) the drain electrodes of the thin film transistors through contact holes penetrating the insulation layer 140, respectively. For example, the third electrode 146 may contact the drain electrode 134 of the thin film transistor T through a contact hole 145.

In an example embodiment, the first, second and third electrodes 152, 154 and 156 may serve as pixel electrodes corresponding to the first, second and third sub-pixel areas 10, 20 and 30, respectively. Further, the first, second and third electrodes 152, 154 and 156 may be anodes for supplying holes to the first, second and third organic light emitting structures 172, 174 and 176.

In an example embodiment, the first, second and third electrodes 152, 154 and 156 may be formed by a sputtering process, a vacuum evaporation process, a CVD process, a pulsed laser deposition process, a printing process, an atomic layer deposition process, etc.

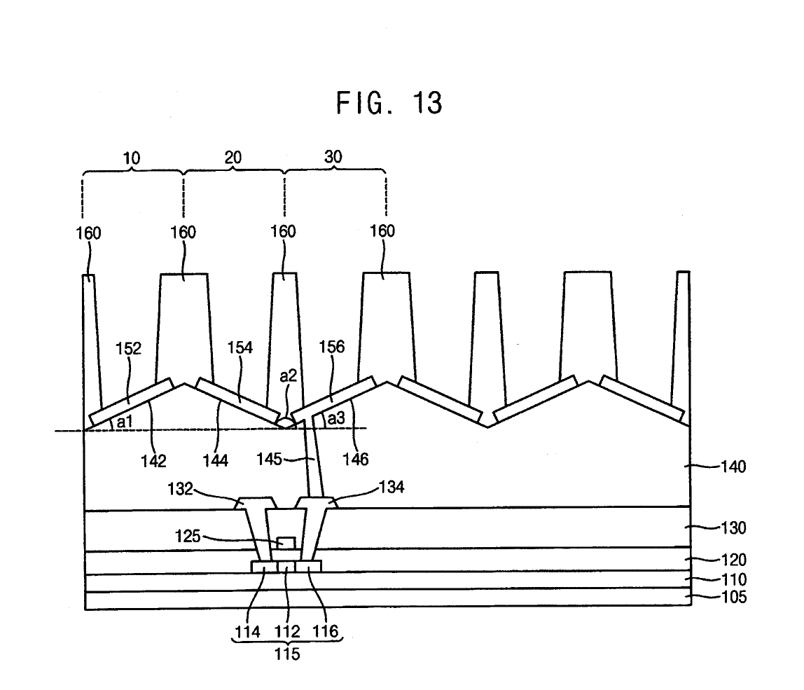

As illustrated in FIG. 13, the pixel defining layer 160 for defining the first, second and third sub-pixel areas 10, 20 and 30 may be formed on the insulation layer 140. In an example embodiment, the pixel defining layer 160 may be formed on a portion of the insulation layer 140 and on a portion of the first, second and third electrodes 152, 154 and 156. A surface of the pixel defining layer 160 may be parallel or substantially parallel to the display substrate 105. Portions of the first, second and third electrodes 152, 154 and 156 exposed by the pixel defining layer 160 may correspond to the luminescent regions of the first, second and third sub-pixel areas, respectively. In an example embodiment, the pixel defining layer 160 may be formed by a photolithography process using (or utilizing) a mask.

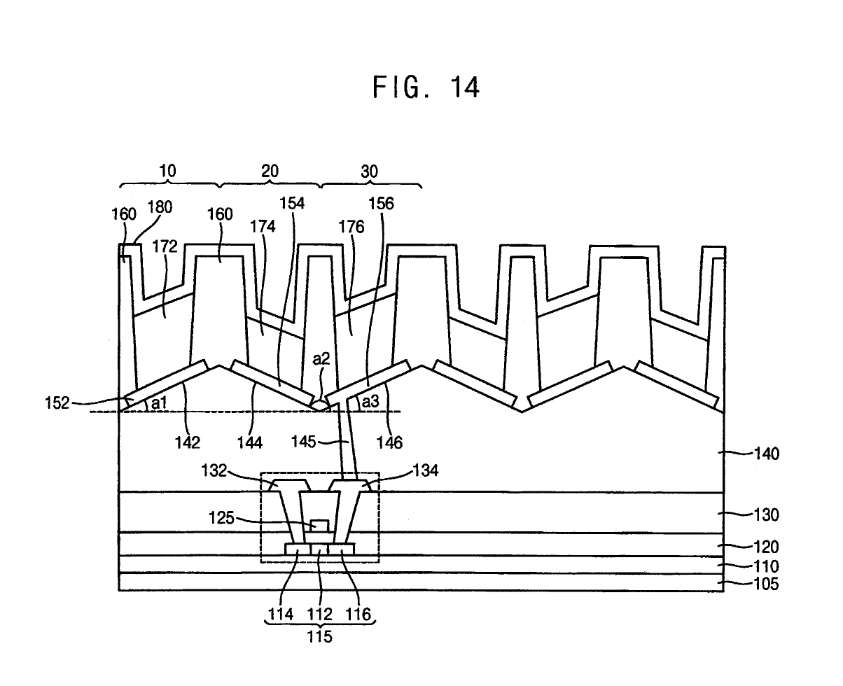

As illustrated in FIG. 14, the first, second and third organic light emitting structures 172, 174 and 176 may be respectively formed on the first, second and third electrodes 152, 154 and 156 (S140), and the common electrode 180 may be formed on the first, second and third organic light emitting structures 172, 174 and 176 (S150).

The first organic light emitting structure 172 may have a uniform thickness, and a surface of the first organic light emitting structures 172 may be parallel to or substantially parallel to the first plane 142. The second and third light emitting structures 174 and 176 may have respective uniform thickness, and surfaces of the second and third organic light emitting structures 174 and 176 may be respectively parallel to or substantially parallel to the second and third planes 144 and 146.

The first, second and third organic light emitting structures 172, 174 and 176 may include first, second and third emission layers (EML), respectively. The first, second and third light emitting layers may respectively generate different colors of light. For example, the first organic light emitting structures 172 may include a red color light emission layer, the second organic light emitting structures 174 may include a green color light emission layer, and the third organic light emitting structures 176 may include a blue color light emission layer. The first, second and third emission layers may be formed by a spin coating process, a roll printing process, a nozzle printing process, an inkjet printing process, a transfer process using (or utilizing) a donor substrate, etc.

In some example embodiments, the first, second and third organic light emitting structures 172, 174 and 176 may include at least one of a HIL and a HTL between the first, second and third electrodes 152, 154 and 156 and the first, second and third emission layers, respectively. Further, the first, second and third organic light emitting structures 172, 174 and 176 may include at least one of an EIL and an ETL between the first, second and third emission layers and the common electrode 180, respectively.

The common electrode 180 may be formed on the first, second and third organic light emitting structures 172, 174 and 176, and the pixel defining layer 160. The common electrode 180 may have a thickness that is substantially uniform at the first, second and third light emitting structures 172, 174 and 176, and the pixel defining layer 160. In an example embodiment, the common electrode 180 may extend from the luminescent regions to the non-luminescent regions. In another example embodiment, the common electrode 180 may be formed only in the luminescent regions. The common electrode 180 may include a transparent conductive material such as indium tin oxide (ITO), zinc tin oxide (ZTO), indium zinc oxide (IZO), zinc oxide (ZnOx), gallium oxide (GaOx), tin oxide (SnOx), etc. These may be used (or utilized) alone or in combination thereof. In an example embodiment, the common electrode 180 may be a cathode for supplying electrons to the first, second and third organic light emitting structures 172, 174 and 176. The common electrode 180 may be formed by a sputtering process, a vacuum evaporation process, a CVD process, a pulsed laser deposition process, a printing process, an atomic layer deposition process, etc.

Additionally, an encapsulation substrate covering the common electrode 180 may be formed on the common electrode 180.

As described above, the method of manufacturing the organic light emitting display panel according to example embodiments may form inclined first, second and third organic light emitting structures 172, 174 and 176 with respect to the display substrate 105. Thus, light from the inclined plane may be mixed with side light that is emitted toward a side of the organic light emitting display panel. As a result, side color shift (e.g., blue color shift, yellow color shift, etc) with respect to the front side of the organic light emitting display panel may be improved in addition to the improvement of the WAD.

In addition, surface area of the first, second and third organic light emitting structures 172, 174 and 176 (e.g., the blue color organic light emitting structure) may be increased due to having the inclined planes. Thus, a lifetime of the organic light emitting structures (and the organic light emitting display panel) may be improved (e.g., increased).

The present embodiments may be applied to any display device and any system including the display device. For example, the present embodiments may be applied to display devices, such as a Liquid Crystal Display (LCD) device, an Organic Light Emitting Display (OLED) device, Plasma Display Panel (PDP), etc.

The foregoing is illustrative of example embodiments, and is not to be construed as limiting thereof. Although a few example embodiments have been described, those having ordinary skill in the art will appreciate that various modifications may be possible from the example embodiments without departing from the spirit and scope of the example embodiments described herein. Accordingly, all such modifications are intended to be included within the scope of the example embodiments as defined in the claims, and their equivalents. In the claims, means-plus-function clauses, if any, are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the spirit and scope of the appended claims. The inventive concept is defined by the following claims, with equivalents of the claims to be included therein.

What is claimed is:

1. An organic light emitting display panel comprising:
a first sub-pixel area, a second sub-pixel area adjacent to the first sub-pixel area, and a third sub-pixel area adjacent to the second sub-pixel area;
a display substrate;
an insulation layer on the display substrate, the insulation layer comprising:
a first plane corresponding to the first sub-pixel area;
a second plane corresponding to the second sub-pixel area; and
a third plane corresponding to the third sub-pixel area, at least one of the first, second, and third planes being inclined with respect to the display substrate;
first, second, and third electrodes respectively on the first, second, and third planes;
a pixel defining layer on the insulation layer, the pixel defining layer defining the first, second, and third sub-pixel areas;
first, second, and third organic light emitting structures respectively on the first, second, and third electrodes, the first, second, and third organic light emitting structures being parallel to the first, second, and third planes, respectively; and
a common electrode on the first, second, and third organic light emitting structures.

2. The display panel of claim 1, wherein all of the first, second, and third planes are inclined with respect to the display substrate.

3. The display panel of claim 2, wherein the first and third planes are inclined in a first direction with respect to the display substrate, and the second plane is inclined in a second direction opposite to the first direction with respect to the display substrate.

4. The display panel of claim 3, wherein the first and third planes have inclined angles from about 10 degrees to about 20 degrees with respect to the display substrate, and
wherein the second plane has an inclined angle from about 160 degrees to about 170 degrees with respect to the display substrate.

5. The display panel of claim 3, wherein each of the first, second, and third planes has a convex curved surface.

6. The display panel of claim 2, wherein the first, second, and third planes are inclined in a same direction with respect to the display substrate.

7. The display panel of claim 6, wherein the first, second, and third planes have inclined angles from about 10 degrees to about 20 degrees with respect to the display substrate.

8. The display panel of claim 1, wherein the insulation layer is formed by a photolithography process, an imprinting process, a bar-coating process, or a 3-dimensional (3D) printing process.

9. An organic light emitting display panel comprising:
a first pixel area comprising a first sub-pixel area, a second sub-pixel area, and a third sub-pixel area;
a second pixel area comprising a fourth sub-pixel area, a fifth sub-pixel area, and a sixth sub-pixel area, the second pixel area being adjacent to the first pixel area;
a display substrate;
an insulation layer on the display substrate, the insulation layer comprising:
a first common plane corresponding to the first, second, and third sub-pixel areas; and
a second common plane corresponding to the fourth, fifth, and sixth sub-pixel areas, the first and second common planes being inclined with respect to the display substrate;
first, second, and third electrodes respectively corresponding to the first, second, and third sub-pixel areas on the first common plane;
fourth, fifth, and sixth electrodes respectively corresponding to the fourth, fifth, and sixth sub-pixel areas on the second common plane;
a pixel defining layer on the insulation layer, the pixel defining layer defining the first, second, third, fourth, fifth, and sixth sub-pixel areas;
first, second, and third organic light emitting structures respectively on the first, second, and third electrodes, the first, second, and third organic light emitting structures being parallel to the first common plane;
fourth, fifth, and sixth organic light emitting structures respectively on the fourth, fifth, and sixth electrodes, the fourth, fifth, and sixth organic light emitting structures being parallel to the second common plane; and
a common electrode on the first, second, third, fourth, fifth, and sixth organic light emitting structures.

10. The display panel of claim 9, wherein the first common plane is inclined in a first direction with respect to the display substrate, and the second common plane is inclined in a second direction opposite to the first direction with respect to the display substrate.

11. The display panel of claim 10, wherein the first common plane has an inclined angle from about 10 degrees to about 20 degrees with respect to the display substrate, and
wherein the second common plane has an inclined angle from about 160 degrees to about 170 degrees with respect to the display substrate.

12. The display panel of claim 10, wherein each of the first and second common planes has a convex curved surface.

13. The display panel of claim 9, wherein the insulation layer is formed by a photolithography process, an imprinting process, a bar-coating process, or a 3-dimensional (3D) printing process.

14. A method of manufacturing an organic light emitting display panel comprising a first sub-pixel area, a second sub-pixel area adjacent to the first sub-pixel area, and a third sub-pixel area adjacent to the second sub-pixel area, the method comprising:
forming an insulation layer comprising a first plane corresponding to the first sub-pixel area, a second plane corresponding to the second sub-pixel area, and a third plane corresponding to the third sub-pixel area on a display substrate, at least one of the first, second, and third planes being inclined with respect to the display substrate;
forming first, second, and third electrodes on the first, second and third planes, respectively;
forming a pixel defining layer on the insulation layer, the pixel defining layer defining the first, second, and third sub-pixel areas;
forming first, second, and third organic light emitting structures on the first, second, and third electrodes, respectively, the first, second, and third organic light emitting structures being parallel to the first, second, and third planes, respectively; and
forming a common electrode on the first, second, and third organic light emitting structures.

15. The method of claim 14, wherein the first and third planes are inclined in a first direction with respect to the display substrate, and the second plane is inclined in a second direction opposite to the first direction with respect to the display substrate.

16. The method of claim 15, wherein the first and third planes have inclined angles from about 10 degrees to about 20 degrees with respect to the display substrate, and
wherein the second plane has an inclined angle from about 160 degrees to about 170 degrees with respect to the display substrate.

17. The method of claim 15, wherein each of the first, second, and third planes has a convex curved surface.

18. The method of claim 14, wherein the first, second, and third planes are inclined in a same direction with respect to the display substrate.

19. The method of claim 18, wherein the first, second, and third planes have inclined angles from about 10 degrees to about 20 degrees with respect to the display substrate.

20. The method of claim 14, wherein the insulation layer is formed by a photolithography process, an imprinting process, a bar-coating process, or a 3-dimensional (3D) printing process.
